(19) United States
(12) Patent Application Publication
(10) Pub. No.: US 2026/0125545 A1
(43) Pub. Date: May 7, 2026

(54) RESIN COMPOSITION, ARTICLE MADE THEREFROM, AND USE THEREOF

(71) Applicant: ELITE ELECTRONIC MATERIAL (KUNSHAN) CO., LTD., Kunshan City (CN)

(72) Inventors: Yan ZHANG, Kunshan City (CN); Rongtao WANG, Kunshan City (CN); Zheng JIA, Kunshan City (CN); Xueyan JIANG, Kunshan City (CN)

(73) Assignee: ELITE ELECTRONIC MATERIAL (KUNSHAN) CO., LTD., Kunshan City (CN)

(21) Appl. No.: 19/003,389

(22) Filed: Dec. 27, 2024

(30) Foreign Application Priority Data
Nov. 5, 2024 (CN) 202411565299.5

(51) Int. Cl. C08L 15/00; C08L 35/02; C09D 4/06; C09D 115/00; C09D 135/02; H05K 3/00

(52) U.S. Cl. CPC C08L 15/00; C08L 35/02; C09D 4/06; C09D 115/00; C09D 135/02; H05K 3/0094; C08L 2203/20; C08L 2205/025; C08L 2205/035

(57) ABSTRACT

The present disclosure provides a resin composition, including: a component (A): 100 parts by weight of an unhydrogenated maleic anhydride-modified first polyolefin; a component (B): 20 to 100 parts by weight of an acrylate monomer, its oligomer or combination thereof, the acrylate monomer has at least two unsaturated carbon-carbon double bonds; and a component (C): 5 to 160 parts by weight of a benzocyclobutene-modified second polyolefin. In addition, the present disclosure also provides an article made from the resin composition. The resin composition and the product have improvements in one or more properties including solder floating crack rate, copper foil peeling strength, percent of thermal expansion at Z-axis, water absorption ratio, and dissipation factor. The present disclosure also provides a use of the resin composition in the resin filling process of printed circuit boards.

### CROSS-REFERENCE TO RELATED APPLICATIONS

This non-provisional application claims priority under 35 U.S.C. § 119(a) on Patent Application No(s). 202411565299.5 filed in China on Nov. 5, 2024, the entire contents of which are hereby incorporated by reference.

### BACKGROUND

### 1. Technical Field

The present disclosure relates to a resin composition, an article made therefrom and a use thereof, particularly to a resin composition that can be applied to a resin filling process for printed circuit boards (PCB).

### 2. Related Art

With the development of miniaturization in assembling components, PCBs are also becoming increasingly miniaturized and thinner, resulting in a continuous reduction of PCB wiring area. This trend requires higher wiring density for PCBs. The resin filling process is an innovative technology developed to reduce PCB design dimensions to accommodate the assembling components, effectively improving the reliability and manufacturing capability of High Density Interconnect (HDI) technology. At the same time, the resin filling technique addresses issues that cannot be resolved using green oil hole-plugging process or lamination filling. For instance, filling blind/buried/through holes structure in the inner layers with resin or filling open areas in thick copper circuits with resin before lamination balances the conflict between controlling the thickness of the dielectric layer during lamination and the application design of the inner layer resin. For instance, resin filling of through-holes improves reliability issues caused by green oil hole-plugging process. However, in existing technologies, the resin compositions used in the resin filling process are primarily prepared from traditional epoxy resin combined with calcium carbonate, which exhibit poor performance characteristics, including one or more of high water absorption ratio, high dissipation factor, high Z-axis percent of thermal expansion, high percent of curing shrinkage, low copper foil peeling strength, and high solder floating crack rate. Therefore, these resin compositions cannot meet the requirements of printed circuit boards for high-frequency and high-speed information transmission.

### SUMMARY

In view of the above problems in the prior arts, specifically, the current material is unable to meet one or more of the technical demands, the main purpose of the present disclosure is to provide a resin composition, an article made from the resin composition, and a use of the resin composition including a hole plugging process for printed circuit boards, a groove filling process for printed circuit boards, or a circuit filling process for printed circuit boards to solve one or more of the above problems.

In one aspect, the present disclosure provides a resin composition, including:
a component (A): 100 parts by weight of an unhydrogenated maleic anhydride-modified first polyolefin;
a component (B): 20 to 100 parts by weight of an acrylate monomer, its oligomer or a combination thereof, wherein the acrylate monomer has at least two unsaturated carbon-carbon double bonds; and
a component (C): 5 to 160 parts by weight of a benzocyclobutene-modified second polyolefin.

In another aspect, the present disclosure also provides an article made from the resin composition, including a prepreg, a resin film, a laminate or a printed circuit board.

In still another aspect, the present disclosure also provides an article made from the resin composition, comprising a resin cured product obtained by curing the resin composition.

The resin composition and the article made therefrom have at least one of following properties:
a solder floating crack rate as measured by reference to IPC-TM-650 2.4.13.1 of 0%;
a copper foil peeling strength as measured by reference to IPC-TM-650 2.4.8 of greater than or equal to 3.5 lb/in;
a Z-axis percent of thermal expansion as measured by reference to IPC-TM-650 2.4.24.5 of less than or equal to 1.72%;
a water absorption ratio as measured by reference to IPC-TM-650 2.6.2.1 and IPC-TM-650 2.6.16.1 of less than or equal to 0.39%; and
a dissipation factor as measured at 10 GHz by reference to JIS C2565 of less than or equal to 0.0048.

In further still another aspect, the present disclosure provides a use of the resin composition in a resin filling process for printed circuit boards.

The resin filling process for printed circuit boards includes a hole plugging process for printed circuit boards, a groove filling process for printed circuit boards or a circuit filling process for printed circuit boards.

In the hole plugging process for printed circuit boards, at least one hole of the printed circuit board is filled with a resin cured product of the resin composition.

In the groove filling process for printed circuit boards, at least one groove of the printed circuit board is filled with a resin cured product of the resin composition.

In the circuit filling process for printed circuit boards, at least one circuit open area of the printed circuit board is covered with a resin cured product of the resin composition.

### DETAILED DESCRIPTION

The following embodiments further explain the viewpoints of the present disclosure in detail, but do not limit the scope of the present disclosure in any viewpoint.

The terms used herein may be commonly used terms in the relevant field, and the terms used herein should not be understood as limiting the present disclosure, but should be understood as examples of terms used to describe the embodiments. In the case of conflict, the definitions contained herein shall prevail.

Unless otherwise specified, a singular form that is used to describe the components or technical features of the present disclosure also includes a plural form.

The terms “comprise,” “include,” “contain,” “have,” or the like used herein belong to open-ended transitional phrase. Unless otherwise specified, other parts may also be included when using the terms. The terms “consisting of,” “composed by,” “remainder being,” or the like used herein belong to close-ended transitional phrase.

For the convenience of the description, numerical ranges used herein shall be understood as including all of the possible subranges and individual values therein, including integers and decimals.

The value used herein includes all of the values which will be the same as such value after being rounded off.

Unless otherwise specified, the term “monomer” used herein refers to a molecule that can be covalently linked to the same or other molecules to form a polymer.

Unless otherwise specified, the term “polymer” used herein refers to products formed by monomer(s) via polymerization. A polymer may include a homopolymer, a copolymer, etc., but the present disclosure is not limited thereto. Unless otherwise specified, the degree of polymerization (monomer conversion rate) of the polymer is not limited. For instance, it can be a fully polymerized polymer (monomer conversion rate of 100%) or a partially polymerized polymer (monomer conversion rate ranging, such as but not limited to, from 10% to 90%, and also referred to as a “prepolymer” in the present disclosure). The molecular weight of the polymer is not limited. For instance, a polymer composed of 2 to 20 repeating units is referred to as an oligomer (also called low polymer). Generally, an oligomer is a polymer composed of 2 to 5 repeating units.

Unless otherwise specified, the term “copolymer” used herein refers to a product formed by two or more different monomers via polymerization, including random copolymers, alternating copolymers, graft copolymers, or block copolymers, but the present disclosure is not limited thereto. For instance, a styrene-butadiene copolymer is a product formed by only styrene and butadiene monomers via polymerization. For instance, the styrene-butadiene copolymer includes a styrene-butadiene random copolymer, a styrene-butadiene alternating copolymer, a styrene-butadiene graft copolymer, or a styrene-butadiene block copolymer, but the present disclosure is not limited thereto. For instance, the styrene-butadiene block copolymer includes a styrene-butadiene diblock copolymer and a styrene-butadiene-styrene triblock copolymer, but the present disclosure is not limited thereto.

Unless otherwise specified, the term “modification” used herein includes a product derived from a resin with its reactive functional group modified, a product derived from a prepolymerization reaction of a resin and other resins, a product derived from copolymerizing a resin and other resins, and a product derived from a crosslinking reaction of a resin and other resins, etc.

Unless otherwise specified, the term “unsaturated bond” used herein refers to a reactive unsaturated bond, such as an unsaturated double bond with the potential of being crosslinked with other functional groups, such as an unsaturated carbon-carbon double bond with the potential of being crosslinked with other functional groups, but the present disclosure is not limited thereto.

The term “unsaturated carbon-carbon double bond” used herein includes a vinyl group, a vinylbenzyl group, a (meth)acryloyl group, an allyl group or a combination thereof, but the present disclosure is not limited thereto. A vinyl group should be understood as including a vinyl group and a vinylidene group, and a (meth)acryloyl should be understood as including a acryloyl group and a methacryloyl group.

Unless otherwise specified, any compound used herein includes various isomers thereof. For instance, a propyl group should be understood as including isopropyl and n-propyl.

Unless otherwise specified, the term “part(s) by weight” used herein represents weight part(s) in any weight unit, such as kilogram, gram, pound, but the present disclosure is not limited thereto. For instance, 100 parts by weight of the unhydrogenated maleic anhydride-modified first polyolefin may represent 100 kilograms of the unhydrogenated maleic anhydride-modified first polyolefin or 100 pounds of the unhydrogenated maleic anhydride-modified first polyolefin. If the resin solution includes a solvent and a resin, the parts by weight of the (solid or liquid) resin generally refers to the weight unit of the (solid or liquid) resin and does not include the weight unit of the solvent in the solution, while the parts by weight of the solvent refers to the weight unit of the solvent. It should be understood that the features of various embodiments of the present disclosure may be partially or entirely combined with each other.

It should be understood that the following embodiments are illustrative in all aspects and do not limit the present disclosure, and are intended to explain the scope of the technical concept of the present disclosure. Therefore, the scope of the present disclosure is not limited to the disclosed embodiments.

The present disclosure provides a resin composition, including:
a component (A): 100 parts by weight of the unhydrogenated maleic anhydride-modified first polyolefin;
a component (B): 20 to 100 parts by weight of an acrylate monomer, its oligomer or a combination thereof, wherein the acrylate monomer has at least two unsaturated carbon-carbon double bonds; and
a component (C): 5 to 160 parts by weight of a benzocyclobutene-modified second polyolefin.

For instance, in one exemplary embodiment, the unhydrogenated maleic anhydride-modified first polyolefin refers to a polyolefin modified by maleic anhydride. For instance, in one exemplary embodiment, the modification method involving maleic anhydride may include various chemical modification methods known in the art, including addition polymerization modification. The addition polymerization modification includes free radical polymerization, cationic polymerization, anionic polymerization, or coordination polymerization, but the present disclosure is not limited thereto. For instance, in one exemplary embodiment, a maleic anhydride monomer undergoes addition polymerization with one or more polyolefins and forms the unhydrogenated maleic anhydride-modified first polyolefin. For instance, in one exemplary embodiment, a maleic anhydride monomer undergoes addition polymerization with one or more olefin monomers and forms a random, alternating, block, or graft copolymer, which is the unhydrogenated maleic anhydride-modified first polyolefin.

For instance, in one exemplary embodiment, the polyolefin and the olefin monomer in the above modification method may be various polyolefins and olefin monomers known in the field, but the present disclosure is not limited thereto. In other words, maleic anhydride may be used to modify various polyolefins and olefin monomers to obtain the unhydrogenated maleic anhydride-modified first polyolefin of the present disclosure.

For instance, in one exemplary embodiment, the unhydrogenated maleic anhydride-modified first polyolefin in the resin composition may be one type of the unhydrogenated maleic anhydride-modified first polyolefin, or a mixture of two or more types of the unhydrogenated maleic anhydride-modified first polyolefins.

For instance, in one exemplary embodiment, the unhydrogenated maleic anhydride-modified first polyolefin may be various maleic anhydride-modified polyolefins known in the field, including any one of maleic anhydride-adducted polybutadiene, maleic anhydride-adducted polyisoprene, maleic anhydride-adducted styrene-butadiene copolymer, maleic anhydride-adducted styrene-isoprene copolymer, maleic anhydride-styrene copolymer or a combination thereof, but the present disclosure is not limited thereto.

In one exemplary embodiment, for instance, the maleic anhydride-styrene copolymer may be various maleic anhydride-styrene copolymers known in the field, and the molar ratio of styrene (St) to maleic anhydride (MA) may be 1/1, 2/1, 3/1, 4/1, 6/1, 8/1 or 12/1, and the example thereof includes styrene maleic anhydride copolymer products SMA-1000, SMA-2000, SMA-3000, EF-30, EF-40, EF-60 and EF-80 available from Cray Valley, or styrene maleic anhydride copolymer products C400, C500, C700, C900 available from Polyscope, but the present disclosure is not limited thereto.

In the present disclosure, with respect to 100 parts by weight of the unhydrogenated maleic anhydride-modified first polyolefin, the resin composition further includes 5 to 160 parts by weight of a benzocyclobutene-modified second polyolefin, such as 5 parts by weight, 20 parts by weight, 40 parts by weight, 60 parts by weight, 80 parts by weight, 100 parts by weight, 120 parts by weight, 140 parts by weight or 160 parts by weight of the benzocyclobutene-modified second polyolefin, but the present disclosure is not limited thereto.

Preferably, the resin composition includes 20 to 120 parts by weight of the benzocyclobutene-modified second polyolefin.

In one exemplary embodiment, for instance, the benzocyclobutene-modified second polyolefin includes any one of benzocyclobutene-modified heteroatom-containing polyolefin, benzocyclobutene-modified non-heteroatom-containing polyolefin or a combination thereof.

Preferably, the benzocyclobutene-modified second polyolefin includes benzocyclobutene-modified heteroatom-containing polyolefin and benzocyclobutene-modified non-heteroatom-containing polyolefin, and the mass ratio of benzocyclobutene-modified non-heteroatom-containing polyolefin to benzocyclobutene-modified heteroatom-containing polyolefin is 1:3 to 7:1.

In one exemplary embodiment, for instance, the heteroatom-containing polyolefin includes any one of maleic anhydride-adducted polybutadiene, maleic anhydride-adducted polyisoprene, maleic anhydride-adducted styrene-butadiene copolymer, maleic anhydride-adducted styrene-isoprene copolymer, vinyl-polybutadiene-urethane polymer, silane-modified styrene-butadiene copolymer, acryloyl group-terminated polybutadiene, epoxy group-containing polybutadiene or a combination thereof. These components should be understood as including modifications or derivatives thereof.

In one exemplary embodiment, for instance, the non-heteroatom-containing polyolefin includes any one of polybutadiene, polyisoprene, styrene-butadiene copolymer, styrene-isoprene copolymer, styrene-butadiene-divinylbenzene polymer, styrene-ethylene-divinylbenzene polymer, styrene-ethylvinylbenzene-divinylbenzene polymer or a combination thereof. These components should be understood as including modifications or derivatives thereof.

In the present disclosure, with respect to 100 parts by weight of the unhydrogenated maleic anhydride-modified first polyolefin, the resin composition further includes 20 to 100 parts by weight of an acrylate monomer, its oligomer or a combination thereof, wherein the acrylate monomer has at least two unsaturated carbon-carbon double bonds. For instance, 20 parts by weight, 30 parts by weight, 40 parts by weight, 50 parts by weight, 60 parts by weight, 70 parts by weight, 80 parts by weight, 90 parts by weight or 100 parts by weight of the acrylate monomer, its oligomer or a combination thereof in total, wherein the acrylate monomer has at least two unsaturated carbon-carbon double bonds, but the present disclosure is not limited thereto.

The acrylate monomer (having at least two unsaturated carbon-carbon double bonds), its oligomer or a combination thereof may be represented as an acrylate monomer (having at least two unsaturated carbon-carbon double bonds) and/or its oligomer. Compared to an acrylate monomer only having one unsaturated carbon-carbon double bond, the acrylate monomer (having at least two unsaturated carbon-carbon double bonds) of the present disclosure has a higher crosslinking density, and the article made therefrom has a better thermal resistance. In the present disclosure, the type of the acrylate monomer (having at least two unsaturated carbon-carbon double bonds) of the present disclosure and its oligomer is not particularly limited, for instance, the resin composition may include any one or more of the acrylate monomers (having at least two unsaturated carbon-carbon double bonds), or the resin composition may include any one or more of the oligomers of the acrylate monomer (having at least two unsaturated carbon-carbon double bonds), or the resin composition may include a mixer of any one or more of the acrylate monomers (having at least two unsaturated carbon-carbon double bonds) and any one or more of the oligomer of the acrylate monomers (having at least two unsaturated carbon-carbon double bonds).

For instance, in one exemplary embodiment, the acrylate monomer (having at least two unsaturated carbon-carbon double bonds) is preferably a compound having at least two acrylate groups. For instance, in one exemplary embodiment, preferably, the acrylate monomer (having at least two unsaturated carbon-carbon double bonds) is an acrylate monomer having two acrylate groups or three acrylate groups.

Unless otherwise specified, the term “acrylate monomer (having at least two unsaturated carbon-carbon double bonds)” may be referred to as “bifunctional or higher acrylate monomer”. For instance, the bifunctional or higher acrylate monomer and/or its oligomer may be various bifunctional or higher acrylate monomers and/or the oligomers obtained from polymerization of the bifunctional or higher acrylate monomers known in the field. For instance, the bifunctional or higher acrylate monomer and/or its oligomer includes any one of bifunctional acrylate monomer and/or its oligomer, trifunctional acrylate monomer and/or its oligomer, tetrafunctional acrylate monomer and/or its oligomer, pentafunctional acrylate monomer and/or its oligomer, hexafunctional acrylate monomer and/or its oligomer or a combination thereof, and the bifunctional or higher acrylate monomer and its oligomer may be self-made or available from Sartomer, but the present disclosure is not limited thereto.

For instance, in one exemplary embodiment, the acrylate monomer (having at least two unsaturated carbon-carbon double bonds) and its oligomer are in liquid state at room temperature. The relative molecular weight (Mr) of the acrylate monomer (having at least two unsaturated carbon-carbon double bonds) is less than or equal to 2000, and the weight average molecular weight (Mw) of the oligomer obtain from polymerization of the acrylate monomer (having at least two unsaturated carbon-carbon double bonds) is less than or equal to 2000.

For instance, in one exemplary embodiment, the acrylate monomer (having at least two unsaturated carbon-carbon double bonds) and/or its oligomer include any one of tricyclodecane dimethanol di(meth)acrylate and/or its oligomer, dioxane glycol di(meth)acrylate and/or its oligomer, di(propylene glycol) di(meth)acrylate and/or its oligomer, tris(2-hydroxyethyl) isocyanurate tri(meth)acrylate and/or its oligomer, pentaerythritol tri(meth)acrylate and/or its oligomer, pentaerythritol tetra(meth)acrylate and/or its oligomer, di(trimethylolpropane) tetra(meth)acrylate and/or its oligomer, dipentaerythritol penta(meth)acrylate and/or its oligomer, dipentaerythritol hexa(meth)acrylate and/or its oligomer or a combination thereof.

For instance, in one exemplary embodiment, the acrylate monomer (having at least two unsaturated carbon-carbon double bonds) and its oligomer have a glass transition temperature greater than or equal to 80° C. after heated and cured, that is, the cured product of the acrylate monomer (having at least two unsaturated carbon-carbon double bonds) and its oligomer has a glass transition temperature greater than or equal to 80° C. For instance, in one exemplary embodiment, preferably, the acrylate monomer (having at least two unsaturated carbon-carbon double bonds) and its oligomer have a glass transition temperature greater than or equal to 90° C. after heated and cured. Preferably, in one exemplary embodiment, the acrylate monomer (having at least two unsaturated carbon-carbon double bonds) and its oligomer have a glass transition temperature greater than or equal to 150° C. after heated and cured.

In the present disclosure, the acrylate monomer (having at least two unsaturated carbon-carbon double bonds) and its oligomer can not only participate in crosslinking reaction but also serve to dissolve and dilute resin composition. Therefore, for instance, in one exemplary embodiment, preferably, no additional organic solvent is required in the resin composition of the present disclosure.

For instance, in one exemplary embodiment, preferably, the resin composition does not include organic solvent. For instance, in one exemplary embodiment, the resin composition does not include any organic solvent of alcohols, ethers, ketones, aromatic hydrocarbons, acetates and amides or a combination thereof. For instance, in one exemplary embodiment, the resin composition does not include any organic solvent or a combination thereof, including methanol, ethanol, ethylene glycol monomethyl ether, acetone, butanone (also known as methyl ethyl ketone), methyl isobutyl ketone, cyclohexanone, nitrogen methyl pyrrolidone, toluene, xylene, methoxyethyl acetate, ethoxyethyl acetate, propoxyethyl acetate, ethyl acetate, propylene glycol methyl ether acetate, dimethylformamide, dimethylacetamide, or a mixed solvent thereof.

For instance, in one exemplary embodiment, preferably, the organic volatile content of the resin composition is less than or equal to 1.5%, more preferably, the organic volatile content of the resin composition is less than or equal to 1.0%. The lower the organic volatile content of the resin composition is, the better the process ability and yield of the resin filling process is. The organic volatile content may be measured by following method: a inorganic filler-containing varnish below is selected as a sample, and the sample is placed into an aluminum plate, and then heated at a rate of 10° C./min from 50° C. to 550° C. by reference to IPC-TM-650 2.4.24.6(2012), and the weight loss percentage, which represents the organic volatile content of the resin composition, at 150° C. is recorded (in %).

Besides the above components, the resin composition of the present disclosure may further include any one of a polyolefin different from the unhydrogenated maleic anhydride-modified first polyolefin and the benzocyclobutene-modified second polyolefin, an unsaturated carbon-carbon double bond-containing crosslinking agent, a benzoxazine resin, an epoxy resin, an active ester, a phenol resin, an amine curing agent, a polyamide, a polyimide, a cyanate ester resin or a combination thereof as needed.

Unless otherwise specified, in the resin composition of the present disclosure, with respect to 100 parts by weight of the unhydrogenated maleic anhydride-modified first polyolefin, the amount of the unsaturated carbon-carbon double bond-containing crosslinking agent, benzoxazine resin, epoxy resin, active ester, phenolic resin, amine curing agent, polyamide, polyimide or cyanate ester resin is not specifically limited, for instance, it may be 1 part by weight to 100 parts by weight, such as 1 part by weight, 10 parts by weight, 15 parts by weight, 20 parts by weight, 25 parts by weight, 50 parts by weight or 100 parts by weight, but the present disclosure is not limited thereto. With respect to 100 parts by weight of the unhydrogenated maleic anhydride-modified first polyolefin, the amount of the amine curing agent is not specifically limited, for instance, it may be 1 to 25 parts by weight, such as 1 part by weight, 4 parts by weight, 7.5 parts by weight, 12 parts by weight or 25 parts by weight, but the present disclosure is not limited thereto.

For instance, in one exemplary embodiment, the resin composition of the present disclosure may further include a polyolefin (referred to as “other polyolefin”) different from the unhydrogenated maleic anhydride-modified first polyolefin and the benzocyclobutene-modified second polyolefin. The other polyolefin in the present disclosure may be various polyolefins known in the field, and may be any one of commercially available or self-made products or a combination thereof, but the present disclosure is not limited thereto. For instance, the other polyolefin in the present disclosure includes any one of polybutadiene, polyisoprene, styrene-butadiene copolymer, styrene-isoprene copolymer, styrene-butadiene-divinylbenzene polymer, vinyl-polybutadiene-urethane polymer, polymethyl styrene, hydrogenated polybutadiene, hydrogenated polyisoprene, hydrogenated styrene-butadiene-divinylbenzene polymer, hydrogenated styrene-butadiene copolymer, hydrogenated styrene-isoprene copolymer, hydrogenated maleic anhydride-adducted styrene-butadiene copolymer, epoxy group-containing polybutadiene, divinylbenzene-styrene-ethylstyrene copolymer, ethylene-divinylbenzene-styrene copolymer or a combination thereof, but the present disclosure is not limited thereto.

For instance, unless otherwise specified, the divinylbenzene-styrene-ethylstyrene copolymer in the present disclosure may include various divinylbenzene-styrene-ethylstyrene copolymers disclosed in the US Patent Application Publication No. US2007/0129502 A1, all of which are incorporated herein by reference in their entirety.

The unsaturated carbon-carbon double bond-containing crosslinking agent of the resin composition in the present disclosure is any one of divinylbenzene (DVB), divinylnaphthalene, divinylbiphenyl, triallyl isocyanurate (TAIC), triallyl cyanurate (TAC), vinylbenzocyclobutene (VBCB), bis(vinylbenzyl)ether (BVBE), bis(vinylphenyl)ethane (BVPE), trivinyl cyclohexane (TVCH), diallyl bisphenol A (DABPA), bifunctional acrylate (such as but not limited to diallyl isophthalate (DAIP)), butadiene, decadiene, octadiene or a combination thereof.

For instance, the benzoxazine resin in the present disclosure may be various benzoxazine resins known in the field, and the example thereof includes bisphenol A benzoxazine resin, bisphenol F benzoxazine resin, phenolphthalein benzoxazine resin, dicyclopentadiene benzoxazine resin, phosphorus-containing benzoxazine resin, diamine benzoxazine resin and phenyl group-modified, vinyl group-modified or allyl group-modified benzoxazine resin or a combination thereof, but the present disclosure is not limited thereto. The suitable commercial products include products LZ-8270 (phenolphthalein benzoxazine resin), LZ-8298 (phenolphthalein benzoxazine resin), LZ-8280 (bisphenol F benzoxazine resin), LZ-8290 (bisphenol A benzoxazine resin) available from Huntsman, or products KZH-5031 (vinyl group-modified benzoxazine resin), KZH-5032 (phenyl-modified benzoxazine resin) available from Kolon Industries, Inc. Among them, the diamine benzoxazine resin may be diaminodiphenylmethane benzoxazine resin, diaminodiphenyl ether benzoxazine resin, diaminodiphenyl sulfone benzoxazine resin, diaminodiphenyl sulfide benzoxazine resin or a combination thereof, but the present disclosure is not limited thereto.

For instance, the epoxy resin in the present disclosure may be various epoxy resins known in the field. For improving the thermal resistance of the resin composition, the epoxy resin includes any one of a bisphenol A epoxy resin, a bisphenol F epoxy resin, a bisphenol S epoxy resin, a bisphenol AD epoxy resin, a novolac epoxy resin, a trifunctional epoxy resin, a tetrafunctional epoxy resin, a multifunctional novolac epoxy resin, dicyclopentadiene (DCPD) epoxy resin, a phosphorus-containing epoxy resin, a p-xylene epoxy resin, a naphthalene epoxy resin (such as naphthol epoxy resin), a benzofuran epoxy resin, a isocyanate-modified epoxy resin or a combination thereof, but the present disclosure is not limited thereto. For instance, the novolac epoxy resin in the present disclosure may be a phenol novolac epoxy resin, a bisphenol A novolac epoxy resin, a bisphenol F novolac epoxy resin, a biphenyl novolac epoxy resin, a phenol benzaldehyde epoxy resin, a phenol aralkyl novolac epoxy resin or a o-cresol novolac epoxy resin. For instance, the phosphorus-containing epoxy resin in the present disclosure may be DOPO (9,10-dihydro-9-oxa-10-phosphaphenanthrene-10-oxide) epoxy resin, DOPO-HQ epoxy resin or a combination thereof. The DOPO epoxy resin may be one or more selected from DOPO-containing phenol novolac epoxy resin, DOPO-containing o-cresol novolac epoxy resin and DOPO-containing bisphenol-A novolac epoxy resin. The DOPO-HQ epoxy resin may be one or more selected from DOPO-HQ-containing phenol novolac epoxy resin, DOPO-HQ-containing o-cresol novolac epoxy resin and DOPO-HQ-containing bisphenol-A novolac epoxy resin, but the present disclosure is not limited thereto.

The active ester of the resin composition in the present disclosure may be various active polyester resins known in the field, including various commercially available active polyester resin products, and the example thereof includes a dicyclopentadiene-containing polyester resin and a naphthalene-containing polyester resin, such as the active polyester resin products HPC-8000, HPC-8150 or HPC-8800 available from D.I.C. Corporation, but the present disclosure is not limited thereto.

For instance, the phenol resin in the present disclosure may be various phenol resins known in the field, and the example thereof includes but not limited to a novolac resin or a phenoxy resin, wherein the novolac resin includes a phenol novolacresin, an o-cresol novolac resin, a bisphenol A novolac resin, a naphthol novolac resin, a biphenyl novolac resin and a dicyclopentadiene novolac resin, but the present disclosure is not limited thereto.

For instance, the amine curing agent in the present disclosure may be various amine curing agents known in the field, and the example thereof includes at least one of diamino diphenyl sulfone, diamino diphenyl methane, diamino diphenyl ether, diamino diphenyl sulfide and dicyandiamide or a combination thereof, but the present disclosure is not limited thereto.

For instance, the polyamide in the present disclosure may be various polyamides known in the field, and the example thereof includes various commercially available polyamide resin products, but the present disclosure is not limited thereto.

For instance, the polyimide in the present disclosure may be various polyimides known in the field, and the example thereof includes various commercially available polyimide resin products, but the present disclosure is not limited thereto.

For instance, the cyanate ester resin in the present disclosure may be various cyanate ester resins known in the field, such as a compound having a structure of Ar—O—C≡N, where the Ar may be a substituted or unsubstituted aromatic group. For improving the thermal resistance of the resin composition, the example of cyanate ester includes a novolac cyanate ester resin, a bisphenol A cyanate ester resin, a bisphenol F cyanate ester resin, a dicyclopentadiene-containing cyanate ester resin, a naphthalene-containing cyanate ester resin, a phenolphthalein cyanate ester resin, an adamantane cyanate ester resin, a fluorene cyanate ester resin or a combination thereof, but the present disclosure is not limited thereto. Among them, the novolac cyanate ester resin may be a bisphenol A novolac cyanate ester resin, a bisphenol F novolac cyanate ester resin or a combination thereof. For instance, the cyanate ester resin may be cyanate ester resin products Primaset PT-15, PT-30S, PT-60S, BA-200, BA-230S, BA-3000S, BTP-2500, BTP-6020S, DT-4000, DT-7000, ULL950S, HTL-300, CE-320, LVT-50, LeCyavailable from Arxada AG.

Besides the above components, the resin composition of the present disclosure may further include any one of an inorganic filler, flame retardant, curing accelerator, polymerization inhibitor, coloring agent, silane coupling agent, surfactant, toughening agent or a combination thereof.

For instance, the inorganic filler in the present disclosure may be various inorganic fillers known in the field, and the example thereof includes silica (fused, non-fused, porous or hollow type), aluminum oxide, aluminum hydroxide, magnesium oxide, magnesium hydroxide, calcium carbonate, aluminum nitride, boron nitride, aluminum silicon carbide, silicon carbide, titanium dioxide, barium titanate, lead titanate, strontium titanate, calcium titanate, magnesium titanate, barium zirconate, lead zirconate, magnesium zirconate, lead zirconate titanate, zinc molybdate, calcium molybdate, magnesium molybdate, ammonium molybdate, zinc molybdate-modified talc, zinc oxide, zirconium oxide, mica, boehmite (AlOOH), calcined talc, talc, silicon nitride, zirconium tungstate, petalite, calcined kaolin or a combination thereof, but the present disclosure is not limited thereto. In addition, the inorganic filler may be spherical (including solid sphere or hollow sphere), fibrous, plate-like, particulate, flake-like or whisker-like, and may be optionally pretreated by a silane coupling agent. In addition, the color of the inorganic filler is not specifically limited, and may be white, black, light yellow or the like, but the present disclosure is not limited thereto. The preparing method of the inorganic filler is also not specifically limited. For instance, the preparing method of spherical SiO₂ (also referred to as spherical silica) may be a melting method, a chemical synthesis method, a directly combustion method or the like, but the present disclosure is not limited thereto. For instance, in one exemplary embodiment, with respect to 100 parts by weight of the unhydrogenated maleic anhydride-modified first polyolefin, the resin composition of the present disclosure may further include 10 parts by weight to 500 parts by weight of the inorganic filler, preferably 50 parts by weight to 400 parts by weight of the inorganic filler, more preferably 150 parts by weight to 350 parts by weight of the inorganic filler, but the present disclosure is not limited thereto.

For instance, the flame retardant in the present disclosure may be various flame retardants known in the field, such as a phosphorus-containing flame retardant or a bromine-containing flame retardant, but the present disclosure is not limited thereto. The bromine-containing flame retardant preferably includes decabromodiphenyl ethane, and the phosphorus-containing flame retardant preferably includes hydroquinone bis-(diphenyl phosphate), bisphenol A bis-(diphenylphosphate), tri(2-carboxyethyl) phosphine (TCEP), tris(chloroisopropyl) phosphate, trimethyl phosphate (TMP), dimethyl methyl phosphonate (DMMP), resorcinol bis(dixylenyl phosphate) (RDX, such as commercially available products PX-200, PX-201 and PX-202), phosphazene (such as commercially available products SPB-100 or SPH-100 that does not include unsaturated carbon-carbon double bonds, or commercially available product SPV-100 which is an allylphosphazene compound, or self-made or commercially available vinyl phosphazene compounds), ammonium polyphosphate, melamine polyphosphate, 9,10-dihydro-9-oxa-10-phosphaphenanthrene-10-oxide (DOPO) and its derivatives (such as di-DOPO compounds) or resins, diphenylphosphine oxide (DPPO) and its derivatives (such as di-DPPO compounds) or resins, melamine cyanurate, trishydroxyethyl isocyanurate, aluminium phosphinate (such as products OP-930 and OP-935) or a combination thereof.

For instance, in one exemplary embodiment, the flame retardant may be a flame retardant available from Katayama Chemical Industries Co., Ltd., including V1, V2, V3, V4, V5, V7, S-2, S-4, E-4c, E-7c, E-8g, E-9g, E-10g, E-100, B-3, W-10, W-2h, W-20, W-30, W-40, OX-1, OX-2, OX-4, OX-6, OX-6+, OX-7, OX-7+, OX-13, BPE-1, BPE-3, HyP-2, API-9, CMPO, ME-20, C-1R, C-1S, C-3R, C-3S or C-11R, but the present disclosure is not limited thereto. The flame retardant in the present disclosure may include one or more of the above flame retardants. For instance, unless otherwise specified, with respect to 100 parts by weight of the unhydrogenated maleic anhydride-modified first polyolefin, the resin composition of the present disclosure may further include 1 part by weight to 100 parts by weight of the flame retardant, preferably 1 part by weight to 50 parts by weight of the flame retardant, but the present disclosure is not limited thereto.

For instance, the curing accelerator in the present disclosure may include a catalyst, such as a Lewis base or a Lewis acid. Among them, the Lewis base may include one or more of imidazole, boron trifluoride-amine complex, ethyltriphenyl phosphonium chloride, 2-methylimidazole (2 MI), 2-phenyl-1H-imidazole (2PZ), 2-ethyl-4-methylimidazole (2E4MZ), triphenylphosphine (TPP) and 4-dimethylaminopyridine (DMAP). The Lewis acid may include metal salt compounds, such as metal salt compounds of manganese, iron, cobalt, nickel, copper and zinc, such as zinc octanoate or cobalt octanoate. The curing accelerator also includes a curing initiator, such as a peroxide capable of producing free radicals. The curing initiator includes dicumyl peroxide (DCP), tert-butyl perbenzoate, dibenzoyl peroxide (BPO), 2,5-dimethyl-2,5-di(tert-butylperoxy)-3-hexyne (DYBP), 2,5-dimethyl-2,5-di-tert-butylperoxy-3-hexyne (DTBP), bis(tert-butylperoxyisopropyl)benzene or a combination thereof, but the present disclosure is not limited thereto. For instance, in one exemplary embodiment, with respect to 100 parts by weight of the unhydrogenated maleic anhydride-modified first polyolefin, the resin composition of the present disclosure may further include 0.001 parts by weight to 20 parts by weight of the curing accelerator, preferably 0.01 parts by weight to 15 parts by weight of the curing accelerator, more preferably 1 part by weight to 10 parts by weight of the curing accelerator, but the present disclosure is not limited thereto.

For instance, the polymerization inhibitor in the present disclosure may include 1,1-diphenyl-2-picrylhydrazyl radical, methyl acrylonitrile, nitroxide-mediated radical, triphenylmethyl radical, metal ion radical, sulfur radical (such as dithioesterbut the present disclosure is not limited thereto), hydroquinone, p-methoxyphenol, p-benzoquinone, phenothiazine, β-phenylnaphthylamine, p-tert-butylcatechol, methylene blue, 4,4′-butylidenebis(6-tert-butyl-3-methylphenol), 2,2′-methylenebis(4-ethyl-6-t-butylphenol) or a combination thereof, but the present disclosure is not limited thereto. For instance, the nitroxide-mediated radical may include nitroxide radicals derived from cyclic hydroxylamines, such as 2,2,6,6-tetramethylpiperidin-1-oxyl free radical, 2,2,6,6-substituted piperidine 1-oxyl free radical or 2,2,5,5-substituted pyrrolidine 1-oxyl free radical, but the present disclosure is not limited thereto. As a substituent, the alkyl group having less than 4 carbon atoms, such as a methyl group or an ethyl group, is preferred. The specific nitroxide-mediated radical is not specifically limited, and may include 2,2,6,6-tetramethylpiperidin-1-oxyl free radical, 2,2,6,6-tetraethylpiperidin-1-oxyl free radical, 2,2,6,6-tetramethyl-4-oxopiperidin-1-oxyl free radical, 2,2,5,5-tetramethylpyrrolidine-1-oxyl free radical, 1,1,3,3-tetramethyl-2-isoindoline oxygen radical, N,N-di-tert-butylamine oxygen free radical or the like, but the present disclosure is not limited thereto. The nitroxide radicals may also be replaced by using stable radicals such as galvinoxyl radicals. The polymerization inhibitor that can applied to the resin composition of the present disclosure may also be products derived from the polymerization inhibitor with its hydrogen atom or group substituted by other atom or group, such as products derived from a polymerization inhibitor with its hydrogen atom substituted by an amino group, a hydroxyl group, a carbonyl group or the like. For instance, in one exemplary embodiment, with respect to 100 parts by weight of the unhydrogenated maleic anhydride-modified first polyolefin, the resin composition of the present disclosure may further include 0.001 parts by weight to 20 parts by weight of the polymerization inhibitor, preferably 0.001 parts by weight to 10 parts by weight of the polymerization inhibitor, but the present disclosure is not limited thereto.

For instance, the coloring agent in the present disclosure may include a dye or a pigment, but the present disclosure is not limited thereto. For instance, in one exemplary embodiment, with respect to 100 parts by weight of the unhydrogenated maleic anhydride-modified first polyolefin, the resin composition of the present disclosure may further include 0.001 parts by weight to 10 parts by weight of the coloring agent, preferably 0.01 parts by weight to 5 parts by weight of the coloring agent, but the present disclosure is not limited thereto.

For instance, the silane coupling agent in the present disclosure may include silane (such as siloxane, but the present disclosure is not limited thereto), and based on the functional group, the silane may be divided into amino silane, epoxide silane, vinyl silane, hydroxyl silane, isocyanate silane, methacryloyloxyl silane and acryloyloxyl silane. For instance, in one exemplary embodiment, with respect to 100 parts by weight of the unhydrogenated maleic anhydride-modified first polyolefin, the resin composition of the present disclosure may further include 0.001 parts by weight to 20 parts by weight of the silane coupling agent, preferably 0.01 parts by weight to 10 parts by weight of the silane coupling agent, but the present disclosure is not limited thereto.

The type of the surfactant of the present disclosure the resin composition is not specifically limited. The main purpose of adding the surfactant in the present disclosure is to make the filler uniformly disperse in the resin composition. For instance, in one exemplary embodiment, with respect to 100 parts by weight of the unhydrogenated maleic anhydride-modified first polyolefin, the resin composition of the present disclosure may further include 0.001 parts by weight to 10 parts by weight of the surfactant, preferably 0.01 parts by weight to 5 parts by weight of the surfactant, but the present disclosure is not limited thereto.

In the present disclosure, the main purpose of adding the toughening agent is to improve the toughness of the resin composition. For instance, the toughening agent in the present disclosure may include carboxyl-terminated butadiene acrylonitrile rubber (CTBN), core-shell rubber, ethylene-propylene rubber or a combination thereof, but the present disclosure is not limited thereto. For instance, in one exemplary embodiment, with respect to 100 parts by weight of the unhydrogenated maleic anhydride-modified first polyolefin, the resin composition of the present disclosure may further include 1 part by weight to 20 parts by weight of the toughening agent, preferably 3 parts by weight to 10 parts by weight of the toughening agent, but the present disclosure is not limited thereto.

For instance, in one exemplary embodiment, the resin composition of each embodiment may be made into various articles, such as assemblies in various electronic products, including a prepreg, a resin film, a laminate or a printed circuit board, but the present disclosure is not limited thereto.

For instance, the resin composition of the present disclosure may be made into a prepreg, which includes a reinforcement material and a layered structure disposed thereon. The layered structure is formed by heating the resin composition at a high temperature to a semi-cured state (B-stage). The baking temperature for making the prepreg is between 120° C. and 180° C., preferably between 120° C. and 160° C. The reinforcement material may be any one of fiber material, woven fabric and non-woven fabric. The woven fabric preferably includes fiberglass fabrics. The fiberglass fabrics may be various fiberglass fabrics used for printed circuit boards, such as E-glass fabric, D-glass fabric, S-glass fabric, T-glass fabric, L-glass fabric, Q-glass fabric or QL-glass fabric (a glass fabric of a mixed structure made of Q-glass fabric and L-glass fabric); and the type of the fiberglass includes yarns and rovings, in spread form or standard form, and the end face shapes may be round or flat. The non-woven fabric preferably includes liquid crystal polymer non-woven fabric, such as polyester non-woven fabric, polyurethane non-woven fabric and so on, but the present disclosure is not limited thereto. The woven fabric may also include liquid crystal polymer woven fabric, such as polyester woven fabric, polyurethane woven fabric and so on, but the present disclosure is not limited thereto. The reinforcement material may increase the mechanical strength of the prepreg. In one preferred embodiment, the reinforcement material may be pre-treated by a silane coupling agent. The prepreg is subsequently heated and cured (C-stage) to form an insulating layer.

For instance, the resin composition of each embodiment may be made into a resin film, which is prepared by heating and baking to semi-cure (B-stage) the resin composition. The resin composition may be selectively coated on a liquid crystal polymer film, a polytetrafluoroethylene film (PTFE film), a polyethylene terephthalate film (PET film), a polyimide film (PI film), a copper foil (such as a 1-ounce hyper very low profile (HVLP) copper foil with a thickness of 28 mil) or a resin-coated copper (RCC), followed by heating and baking to a semi-cured state so as to make the resin composition into the resin film.

For instance, the resin composition of each embodiment may be made into various laminates, which include at least two metal foils and at least one insulation layer disposed between the two metal foils. The insulation layer may be made by curing the resin composition at high temperature and high pressure to C-stage, wherein a suitable curing temperature may be between 190° C. and 220° C., preferably between 200° C. and 210° C., a curing time may be 90 to 180 minutes, preferably 120 to 150 minutes, and a laminating pressure may be between 300 psi and 550 psi, preferably between 400 psi and 550 psi. The insulation layer may be formed by curing the prepreg or the resin film to C-stage. The material of the metal foil may be copper, aluminum, nickel, platinum, silver, gold, or alloy thereof, such as copper foil (including a 1-ounce hyper very low profile (HVLP) copper foil with a thickness of 28 mil, but the present disclosure is not limited thereto). In one preferred exemplary embodiment, the laminate is a copper-clad laminate (CCL).

In one exemplary embodiment, the laminate may be further processed through a circuit processing to form a printed circuit board. One of the preparing methods of the printed circuit board of the present disclosure is as the following: a double-sided copper-clad laminate (such as product EM-891, available from Elite Electronic Material (Kunshan) Co., Ltd.) with a thickness of 28 mil and having 1-ounce (oz) hyper very low profile (HVLP) copper foils may be used and subject to drilling and then electroplating, so as to form an electrical conduction between the upper layer copper foil and the bottom layer copper foil. Then, the upper layer copper foil and the bottom layer copper foil are etched to form an inner layer circuit board. Then, brown oxidation and roughening processes are performed on the inner layer circuit board to form uneven structures on the surface to increase roughness. Next, a copper foil, the prepreg, the inner layer circuit board, the prepreg and a copper foil are stacked in such sequence, and then heated at 190° C. to 245° C. for 90 minutes to 240 minutes by a vacuum lamination apparatus to cure the material of the insulation layer of the prepreg, and then black oxidation, drilling, copper plating and other processes known in the field are further performed on the outmost copper foil, thereby obtaining a printed circuit board

For instance, in one exemplary embodiment, the article made from the resin composition includes a reinforcement material or a supporting material and a semi-cured or cured product obtained by heating and chemically cross-linking the resin composition.

For instance, in one exemplary embodiment, the present disclosure provides another article, which has a resin cured product obtained by heating to completely cure (C-stage) the resin composition. The curing temperature applicable to the heating process is between 150° C. and 250° C., preferably between 170° C. and 220° C., and the curing time is 60 to 240 minutes, preferably 60 to 180 minutes.

For instance, the shape of the resin cured product is not specifically limited, and may be in the form of layers, blocks, particles, etc. For instance, the method for preparing the resin cured product is not specifically limited. The resin cured product may be obtained by placing it in a mold of a specific shape and heating it to be completely cured, or by coating it on a supporting material and heating it to be completely cured. The mold of specific shape includes but are not limited to laminates or printed circuit boards with grooves, holes of printed circuit boards or circuit open areas of printed circuit boards. For instance, the article only includes the resin cured product obtained by curing the resin composition. For instance, the article includes the resin cured product obtained by curing the resin composition and a supporting material. The supporting material includes a liquid crystal polymer film, a polytetrafluoroethylene film (PTFE film), a polyethylene terephthalate film (PET film), a polyimide film (PI film) and a metal foil, but the present disclosure is not limited thereto.

The present disclosure also provides a use of the resin composition in a resin filling process for printed circuit boards (PCB). For instance, the resin filling process include a hole plugging process for printed circuit boards, a groove filling process for printed circuit boards, and a circuit filling process for printed circuit boards, but the present disclosure is not limited thereto. In one exemplary embodiment, the present disclosure also provides a use of the resin composition in a hole plugging process for printed circuit boards. For instance, in a process for preparing printed circuit boards, a laminate is subjected to drilling, and optionally to electroplating as needed, followed by hole plugging. For instance, the laminate may be subject to electroplating after drilling, so as to form an electrical conduction between the upper layer copper foil and the bottom layer copper foil, and then subjected to hole plugging. Alternatively, the laminate may be subject to hole plugging after drilling, and then the laminate subjected to hole plugging is subjected to secondary drilling, wherein the hole diameter of secondary drilling is usually smaller than the hole diameter of primary drilling, and then copper is electroplated on the walls of secondary drilled holes. The resin composition of the present disclosure is especially suitable to be applied to the hole plugging process for printed circuit boards. The resin composition of the present disclosure may be plugged into holes and completely cured, followed by various processes for circuit boards known in the field. For instance, in one exemplary embodiment, at least one hole of the printed circuit board is filled with the resin cured product of the resin composition, followed by performing various processes for circuit boards known in the field on the printed circuit board.

In one exemplary embodiment, the present disclosure also provides a use of the resin composition in a groove filling process for printed circuit boards. For instance, in a process for preparing printed circuit boards, a groove is formed in the non-wiring area of the laminate, and the groove is filled with resin varnish, cured, and planarized, followed by various processes for circuit boards known in the field. For instance, in one exemplary embodiment, at least one groove of the printed circuit board is filled with the resin cured product of the resin composition, followed by performing various processes for circuit boards known in the field on the printed circuit board, wherein the wall of the groove may be electroplated or non-electroplated.

In one exemplary embodiment, the present disclosure also provides a use of the resin composition in a circuit filling process for printed circuit boards. For instance, in a process for preparing printed circuit boards, a laminate is subjected to a circuit process and formed an inner layer circuit board, and optionally subjected to circuit filling according to the thickness of the copper in the inner layer circuit board. The resin composition of the present disclosure is especially suitable to be applied to the circuit filling process for printed circuit boards. The resin composition of the present disclosure may be filled into circuit open areas (i.e., areas without circuits) and completely cured, followed by various processes for circuit boards known in the field. For instance, in one exemplary embodiment, at least one circuit open area of the printed circuit board is covered with the resin cured product of the resin composition, followed by performing various processes for circuit boards known in the field on the printed circuit board.

For instance, in one exemplary embodiment, the resin composition disclosed in the present disclosure or various articles made therefrom including the resin cured product, preferably have at least one of following properties:
a solder floating crack rate as measured by reference to IPC-TM-650 2.4.13.1 of 0%;
a copper foil peeling strength as measured by reference to IPC-TM-650 2.4.8 of greater than or equal to 3.5 lb/in, such as between 3.5 lb/in and 5.1 lb/in, and such as between 4.0 lb/in and 5.1 lb/in;
a Z-axis percent of thermal expansion as measured by reference to IPC-TM-650 2.4.24.5 of less than or equal to 1.72%, such as between 1.15% and 1.72%, and such as between 1.15% and 1.60%;
a water absorption ratio as measured by reference to IPC-TM-650 2.6.2.1 and IPC-TM-650 2.6.16.1 of less than or equal to 0.39%, such as between 0.08% and 0.39%; and
a dissipation factor as measured at 10 GHz by reference to JIS C2565 of less than or equal to 0.0048, such as between 0.0030 and 0.0048.

Raw materials below are used to prepare the resin compositions of Examples and Comparative Examples of the present disclosure according to the amount listed in Table 1 to Table 6 and further made into testing samples or articles.

The chemical materials used in Examples and Comparative Examples of the present disclosure are described as follows:

A1: Ricon 131MA5: unhydrogenated maleic anhydride-adducted polybutadiene, available from Cray Valley SA.

A2: Ricon 130MA8: unhydrogenated maleic anhydride-adducted polybutadiene, available from Cray Valley SA.

A3: Ricon 130MA13: unhydrogenated maleic anhydride-adducted polybutadiene, available from Cray Valley SA.

A4: Ricon 131MA10: unhydrogenated maleic anhydride-adducted polybutadiene, available from Cray Valley SA.

A5: Ricon 156MA17: unhydrogenated maleic anhydride-adducted polybutadiene, available from Cray Valley SA.

A6: Ricon 184MA6: unhydrogenated maleic anhydride-adducted styrene-butadiene copolymer, available from Cray Valley SA.

A7: EF80: unhydrogenated maleic anhydride-styrene copolymer, available from Cray Valley SA.

SR833S: tricyclodecane dimethanol diacrylate, having a structure below, available from Sartomer, and the glass transition temperature of its cured product is about 180° C.

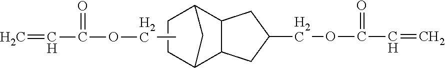

SR368NS: tris(2-hydroxyethyl) isocyanurate triacrylate, having a structure below, available from Sartomer, and the glass transition temperature of its cured product is about 272° C.

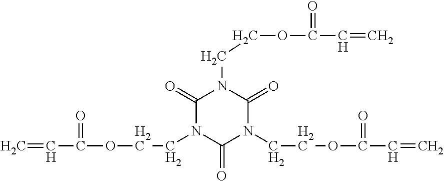 [SMILES: C=CC(=O)OCCn1c(=O)n(CCOC(=O)C=C)c(=O)n(CCOC(=O)C=C)c1=O]

Oligomer of SR833S: oligomer of tricyclodecane dimethanol diacrylate, formed by tricyclodecane dimethanol diacrylate via polymerization, with a weight average molecular weight less than 2000, and the glass transition temperature of its cured product is about 180° C.

SR295 NS: pentaerythritol tetraacrylate, having a structure below, available from Sartomer, and the glass transition temperature of its cured product is about 103° C.

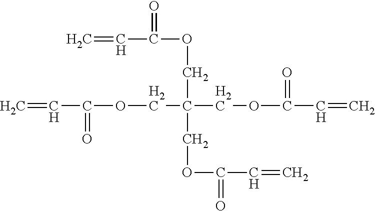 [SMILES: C=CC(=O)OCC(COC(=O)C=C)(COC(=O)C=C)COC(=O)C=C]

SR399 NS: dipentaerythritol pentaacrylate, having a structure below, available from Sartomer, and the glass transition temperature of its cured product is about 90° C.

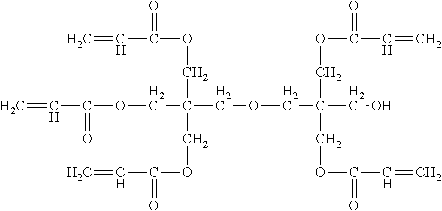 [SMILES: C=CC(=O)OCC(CO)(COCC(COC(=O)C=C)(COC(=O)C=C)COC(=O)C=C)COC(=O)C=C]

DPHA: dipentaerythritol hexaacrylate, having a structure below, available from Sartomer, and the glass transition temperature of its cured product is about 90° C.

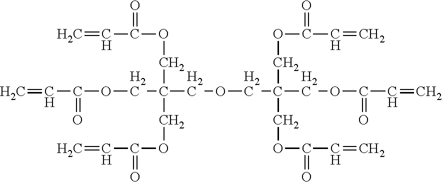 [SMILES: C=CC(=O)OCC(COCC(COC(=O)C=C)(COC(=O)C=C)COC(=O)C=C)(COC(=O)C=C)COC(=O)C=C]

P1: self-made, as described below.

P2: self-made, as described below.

P3: self-made, as described below.

P4: self-made, as described below.

P5: self-made, as described below.

P6: self-made, as described below.

P7: self-made, as described below.

P8: self-made, as described below.

P9: self-made, as described below.

P10: self-made, as described below.

TAIC: triallyl isocyanurate, available from Kingyorker Enterprise Co., Ltd.

Ricon 100: styrene-butadiene copolymer, available from Cray Valley SA.

Ricon 130: polybutadiene, available from Cray Valley SA.

FG1901: hydrogenated maleic anhydride-modified styrene-butadiene copolymer, available from KRATON.

BVPE: bis(vinylphenyl)ethane, available from Linchuan Chemical Co., Ltd.

DVB: divinylbenzene, available from Shanghai Macklin Biochemical Technology Co., Ltd.

B1000: polybutadiene, available from Nippon Soda Co., Ltd.

B3000: polybutadiene, available from Nippon Soda Co., Ltd.

SBS-A: styrene-butadiene block copolymer, available from Nippon Soda Co., Ltd.

X-12-1281A-ES: triethoxysilane-modified styrene-butadiene copolymer, available from Shin-Etsu Chemical Co., Ltd.

EA-3000:1,2-polybutadiene modified by an acryloyl group at terminal, available from Nippon Soda Co., Ltd.

JP-100: epoxy group-containing polybutadiene, available from Nippon Soda Co., Ltd.

Chemically synthesized spherical silicon dioxide (spherical SiO₂): a spherical silicon dioxide with a median particle size D50 of about 1.5±0.5 μm, prepared by microemulsion method and treated by a silane coupling agent, available from Suzhou Ginet new material technology Co. Ltd.

### Preparation Example 1: P1

200 g of B1000, 183 g of 4-bromobenzocyclobutene, 4.5 g of palladium acetate, 30.4 g of tris(o-tolyl)phosphine, 202 g of triethylamine, and 2000 mL of mixed solvent of anhydrous acetonitrile/N,N-dimethylformamide (DMF) are added into a reactor to form a solution. The solution is evacuated and filled with nitrogen three times. Under nitrogen atmosphere, the solution is then heated and refluxed for 36 hours, and the conversion rate of 4-bromobenzocyclobutene is monitored by gas chromatography. Once the desired conversion rate (>50%) is achieved, the heating process is stopped. After the solution is cooled to room temperature, petroleum ether is added thereto and stirred. The solution is filtered under vacuum to remove the salts and palladium catalyst formed during the reaction to obtain a filtrate. The filtrate is then purified by column chromatography and rotary evaporation to obtain a pale yellow viscous liquid P1.

### Preparation Example 2: P2

200 g of B3000, 183 g of 4-bromobenzocyclobutene, 4.5 g of palladium acetate, 30.4 g of tris(o-tolyl)phosphine, 202 g of triethylamine, and 3000 mL of mixed solvent of anhydrous acetonitrile/DMF are added into a reactor to form a solution. The solution is evacuated and filled with nitrogen three times. Under nitrogen atmosphere, the solution is then heated and refluxed for 48 hours, and the conversion rate of 4-bromobenzocyclobutene is monitored by gas chromatography. Once the desired conversion rate (>50%) is achieved, the heating process is stopped. After the solution is cooled to room temperature, petroleum ether is added thereto and stirred. The solution is filtered under vacuum to remove the salts and palladium catalyst formed during the reaction to obtain a filtrate. The filtrate is then purified by column chromatography and rotary evaporation to obtain a pale yellow viscous liquid P2.

### Preparation Example 3: P3

450 g of Ricon100, 183 g of 4-bromobenzocyclobutene, 6.75 g of palladium acetate, 36.48 g of tris(o-tolyl)phosphine, 202 g of triethylamine, and 3500 mL of mixed solvent of anhydrous acetonitrile/DMF are added into a reactor to form a solution. The solution is evacuated and filled with nitrogen three times. Under nitrogen atmosphere, the solution is then heated and refluxed for 72 hours, and the conversion rate of 4-bromobenzocyclobutene is monitored by gas chromatography. Once the desired conversion rate (>50%) is achieved, the heating process is stopped. After the solution is cooled to room temperature, petroleum ether is added thereto and stirred. The solution is filtered under vacuum to remove the salts and palladium catalyst formed during the reaction to obtain a filtrate. The filtrate is then purified by column chromatography and rotary evaporation to obtain a pale yellow viscous liquid P3.

### Preparation Example 4: P4

260 g of SBS-A, 128.1 g of 4-bromobenzocyclobutene, 4.5 g of palladium acetate, 30.4 g of tris(o-tolyl)phosphine, 101 g of triethylamine, and 3000 mL of mixed solvent of anhydrous acetonitrile/cyclohexane/DMF are added into a reactor to form a solution. The solution is evacuated and filled with nitrogen three times. Under nitrogen atmosphere, the solution is then heated and refluxed for 72 hours, and the conversion rate of 4-bromobenzocyclobutene is monitored by gas chromatography. Once the desired conversion rate (>50%) is achieved, the heating process is stopped. After the solution is cooled to room temperature, petroleum ether is added thereto and stirred. The solution is filtered under vacuum to remove the salts and palladium catalyst formed during the reaction to obtain a filtrate. The filtrate is then purified by column chromatography and rotary evaporation to obtain a pale yellow viscous solid P4.

### Preparation Example 5: P5

470 g of Ricon 131MA5, 183 g of 4-bromobenzocyclobutene, 6.75 g of palladium acetate, 36.48 g of tris(o-tolyl)phosphine, 202 g of triethylamine, and 3500 mL of mixed solvent of anhydrous acetonitrile/DMF are added into a reactor to form a solution. The solution is evacuated and filled with nitrogen three times. Under nitrogen atmosphere, the solution is then heated and refluxed for 50 hours, and the conversion rate of 4-bromobenzocyclobutene is monitored by gas chromatography. Once the desired conversion rate (>50%) is achieved, the heating process is stopped. After the solution is cooled to room temperature, petroleum ether is added thereto and stirred. The solution is filtered under vacuum to remove the salts and palladium catalyst formed during the reaction to obtain a filtrate. The filtrate is then purified by column chromatography and rotary evaporation to obtain a yellow viscous liquid P5.

### Preparation Example 6: P6

250 g of Ricon 156MA17, 183 g of 4-bromobenzocyclobutene, 6.75 g of palladium acetate, 36.48 g of tris(o-tolyl)phosphine, 202 g of triethylamine, and 3500 mL of mixed solvent of anhydrous acetonitrile/DMF are added into a reactor to form a solution. The solution is evacuated and filled with nitrogen three times. Under nitrogen atmosphere, the solution is then heated and refluxed for 60 hours, and the conversion rate of 4-bromobenzocyclobutene is monitored by gas chromatography. Once the desired conversion rate (>50%) is achieved, the heating process is stopped. After the solution is cooled to room temperature, petroleum ether is added thereto and stirred. The solution is filtered under vacuum to remove the salts and palladium catalyst formed during the reaction to obtain a filtrate. The filtrate is then purified by column chromatography and rotary evaporation to obtain a yellow viscous liquid P6.

### Preparation Example 7: P7

455 g of Ricon 184MA6, 128.1 g of 4-bromobenzocyclobutene, 4.5 g of palladium acetate, 30.4 g of tris(o-tolyl)phosphine, 101 g of triethylamine, and 3000 mL of mixed solvent of anhydrous acetonitrile/DMF are added into a reactor to form a solution. The solution is evacuated and filled with nitrogen three times. Under nitrogen atmosphere, the solution is then heated and refluxed for 72 hours, and the conversion rate of 4-bromobenzocyclobutene is monitored by gas chromatography. Once the desired conversion rate (>50%) is achieved, the heating process is stopped. After the solution is cooled to room temperature, petroleum ether is added thereto and stirred. The solution is filtered under vacuum to remove the salts and palladium catalyst formed during the reaction to obtain a filtrate. The filtrate is then purified by column chromatography and rotary evaporation to obtain a yellow viscous liquid P7.

### Preparation Example 8: P8

455 g of X-12-1281A-ES, 128.1 g of 4-bromobenzocyclobutene, 4.5 g of palladium acetate, 30.4 g of tris(o-tolyl)phosphine, 101 g of triethylamine, and 3000 mL of mixed solvent of anhydrous acetonitrile/cyclohexane/DMF are added into a reactor to form a solution. The solution is evacuated and filled with nitrogen three times. Under nitrogen atmosphere, the solution is then heated and refluxed for 72 hours, and the conversion rate of 4-bromobenzocyclobutene is monitored by gas chromatography. Once the desired conversion rate (>50%) is achieved, the heating process is stopped. After the solution is cooled to room temperature, petroleum ether is added thereto and stirred. The solution is filtered under vacuum to remove the salts and palladium catalyst formed during the reaction to obtain a filtrate. The filtrate is then purified by column chromatography and rotary evaporation to obtain a pale yellow viscous solid P8.

### Preparation Example 9: P9

200 g of EA-3000, 183 g of 4-bromobenzocyclobutene, 4.5 g of palladium acetate, 30.4 g of tris(o-tolyl)phosphine, 202 g of triethylamine, and 3000 mL of mixed solvent of anhydrous acetonitrile/DMF are added into a reactor to form a solution. The solution is evacuated and filled with nitrogen three times. Under nitrogen atmosphere, the solution is then heated and refluxed for 48 hours, and the conversion rate of 4-bromobenzocyclobutene is monitored by gas chromatography. Once the desired conversion rate (>50%) is achieved, the heating process is stopped. After the solution is cooled to room temperature, petroleum ether is added thereto and stirred. The solution is filtered under vacuum to remove the salts and palladium catalyst formed during the reaction to obtain a filtrate. The filtrate is then purified by column chromatography and rotary evaporation to obtain a yellow viscous liquid P9.

### Preparation Example 10: P10

260 g of JP-100, 183 g of 4-bromobenzocyclobutene, 4.5 g of palladium acetate, 30.4 g of tris(o-tolyl)phosphine, 202 g of triethylamine, and 2000 mL of mixed solvent of anhydrous acetonitrile/DMF are added into a reactor to form a solution. The solution is evacuated and filled with nitrogen three times. Under nitrogen atmosphere, the solution is then heated and refluxed for 40 hours, and the conversion rate of 4-bromobenzocyclobutene is monitored by gas chromatography. Once the desired conversion rate (>50%) is achieved, the heating process is stopped. After the solution is cooled to room temperature, petroleum ether is added thereto and stirred. The solution is filtered under vacuum to remove the salts and palladium catalyst formed during the reaction to obtain a filtrate. The filtrate is then purified by column chromatography and rotary evaporation to obtain a pale yellow viscous liquid P10.

Components and property testing results of the resin composition of Examples and Comparative Examples are shown in Table 1 to Table 6 (in parts by weight):

TABLE 1
The components (in parts by weight) and the property testing
results of the resin composition of Examples E1 to E6

| Components | | E1 | E2 | E3 | E4 | E5 | E6 |
|---|---|---|---|---|---|---|---|
| (A) unhydrogenated | A1 | — | — | — | — | — | — |
| maleic anhydride- | A2 | 100 | 100 | 100 | 100 | 100 | 100 |
| modified first | A3 | — | — | — | — | — | — |
| polyolefin | A4 | — | — | — | — | — | — |
| | A5 | — | — | — | — | — | — |
| | A6 | — | — | — | — | — | — |
| | A7 | — | — | — | — | — | — |
| (B) acrylate | SR833S | 60 | 60 | 60 | 60 | 20 | 100 |
| monomer or its | SR368NS | — | — | — | — | — | — |
| oligomer | Oligomer of | — | — | — | — | — | — |
| | SR833S | | | | | | |
| | SR295 NS | — | — | — | — | — | — |
| | SR399 NS | — | — | — | — | — | — |
| | DPHA | — | — | — | — | — | — |
| (C) | P1 | 40 | 5 | 20 | 160 | 40 | 40 |
| benzocyclobutene- | P2 | — | — | — | — | — | — |
| modified second | P3 | — | — | — | — | — | — |
| polyolefin | P4 | — | — | — | — | — | — |
| | P5 | — | — | — | — | — | — |
| | P6 | — | — | — | — | — | — |
| | P7 | — | — | — | — | — | — |
| | P8 | — | — | — | — | — | — |
| | P9 | — | — | — | — | — | — |
| | P10 | — | — | — | — | — | — |
| Other polyolefin | Ricon 130 | — | — | — | — | — | — |
| different from (A) | Ricon100 | — | — | — | — | — | — |
| and (C) | FG1901 | — | — | — | — | — | — |
| Unsaturated carbon- | BVPE | — | — | — | — | — | — |
| carbon double bond- | DVB | — | — | — | — | — | — |
| containing | | | | | | | |
| crosslinking agent | | | | | | | |
| Curing accelerator | DCP | 3.0 | 3.0 | 3.0 | 3.0 | 3.0 | 3.0 |
| Inorganic filler | Spherical SiO₂ | 260 | 260 | 260 | 260 | 260 | 260 |

| Properties | Unit | E1 | E2 | E3 | E4 | E5 | E6 |
|---|---|---|---|---|---|---|---|
| Solder floating crack | % | 0 | 0 | 0 | 0 | 0 | 0 |
| rate | | | | | | | |
| Copper foil peeling | lb/in | 4.30 | 4.50 | 4.40 | 3.50 | 4.00 | 4.50 |
| strength | | | | | | | |
| Z-axis percent of | % | 1.55 | 1.67 | 1.62 | 1.15 | 1.39 | 1.62 |
| thermal expansion | | | | | | | |
| Water absorption | % | 0.20 | 0.39 | 0.25 | 0.08 | 0.15 | 0.38 |
| ratio | | | | | | | |
| Dissipation factor | / | 0.0039 | 0.0048 | 0.0042 | 0.0030 | 0.0036 | 0.0047 |

TABLE 2
The components (in parts by weight) and the property testing
results of the resin composition of Examples E7 to E12

| Components | | E7 | E8 | E9 | E10 | E11 | E12 |
|---|---|---|---|---|---|---|---|
| (A) | A1 | — | — | — | — | — | — |
| unhydrogenated | A2 | 100 | 100 | 100 | 100 | 100 | — |
| maleic anhydride- | A3 | — | — | — | — | — | — |
| modified first | A4 | — | — | — | — | — | 100 |
| polyolefin | A5 | — | — | — | — | — | — |
| | A6 | — | — | — | — | — | — |
| | A7 | — | — | — | — | — | — |
| (B) acrylate | SR833S | — | — | — | — | — | — |
| monomer or its | SR368NS | 60 | — | — | — | — | 50 |
| oligomer | Oligomer of | — | 60 | — | — | — | — |
| | SR833S | | | | | | |
| | SR295 NS | — | — | 60 | — | — | — |
| | SR399 NS | — | — | — | 60 | — | — |
| | DPHA | — | — | — | — | 60 | — |
| (C) | P1 | 40 | 40 | 40 | 40 | 40 | — |
| benzocyclobutene- | P2 | — | — | — | — | — | — |
| modified second | P3 | — | — | — | — | — | 40 |
| polyolefin | P4 | — | — | — | — | — | — |
| | P5 | — | — | — | — | — | — |
| | P6 | — | — | — | — | — | — |
| | P7 | — | — | — | — | — | — |
| | P8 | — | — | — | — | — | — |
| | P9 | — | — | — | — | — | — |
| | P10 | — | — | — | — | — | — |
| Other polyolefin | Ricon 130 | — | — | — | — | — | — |
| different from (A) | Ricon100 | — | — | — | — | — | — |
| and (C) | FG1901 | — | — | — | — | — | — |
| Unsaturated | BVPE | — | — | — | — | — | — |
| carbon-carbon | DVB | — | — | — | — | — | — |
| double bond- | | | | | | | |
| containing | | | | | | | |
| crosslinking agent | | | | | | | |
| Curing accelerator | DCP | 3.0 | 3.0 | 3.0 | 3.0 | 3.0 | 3.0 |
| Inorganic filler | Spherical SiO₂ | 260 | 260 | 260 | 260 | 260 | 260 |

| Properties | Unit | E7 | E8 | E9 | E10 | E11 | E12 |
|---|---|---|---|---|---|---|---|
| Solder floating | % | 0 | 0 | 0 | 0 | 0 | 0 |
| crack rate | | | | | | | |
| Copper foil peeling | lb/in | 4.40 | 4.20 | 4.30 | 4.20 | 4.40 | 4.30 |
| strength | | | | | | | |
| Z-axis percent of | % | 1.49 | 1.61 | 1.70 | 1.72 | 1.71 | 1.56 |
| thermal expansion | | | | | | | |
| Water absorption | % | 0.23 | 0.19 | 0.24 | 0.26 | 0.25 | 0.18 |
| ratio | | | | | | | |
| Dissipation factor | / | 0.0042 | 0.0043 | 0.0044 | 0.0046 | 0.0045 | 0.0038 |

TABLE 3
The components (in parts by weight) and the property testing
results of the resin composition of Examples E13 to E17

| Components | | E13 | E14 | E15 | E16 | E17 |
|---|---|---|---|---|---|---|
| (A) | A1 | — | — | — | — | — |
| unhydrogenated | A2 | — | — | 100 | 100 | 100 |
| maleic anhydride- | A3 | — | — | — | — | — |
| modified first | A4 | — | — | — | — | — |
| polyolefin | A5 | 100 | — | — | — | — |
| | A6 | — | 100 | — | — | — |
| | A7 | — | — | — | — | — |
| (B) acrylate | SR833S | — | — | 60 | 60 | 60 |
| monomer or its | SR368NS | — | 90 | — | — | — |
| oligomer | Oligomer of | 70 | — | — | — | — |
| | SR833S | | | | | |
| | SR295 NS | — | — | — | — | — |
| | SR399 NS | — | — | — | — | — |
| | DPHA | — | — | — | — | — |
| (C) | P1 | — | — | 35 | 25 | 15 |
| benzocyclobutene- | P2 | — | — | — | — | — |
| modified second | P3 | — | — | — | — | — |
| polyolefin | P4 | — | — | — | — | — |
| | P5 | 80 | — | — | — | — |
| | P6 | — | 120 | — | — | — |
| | P7 | — | — | 5 | 15 | 25 |
| | P8 | — | — | — | — | — |
| | P9 | — | — | — | — | — |
| | P10 | — | — | — | — | — |
| Other polyolefin | Ricon 130 | — | — | — | — | — |
| different from (A) | Ricon100 | — | — | — | — | — |
| and (C) | FG1901 | — | — | — | — | — |
| Unsaturated | BVPE | — | — | — | — | — |
| carbon-carbon | DVB | — | — | — | — | — |
| double bond- | | | | | | |
| containing | | | | | | |
| crosslinking agent | | | | | | |
| Curing accelerator | DCP | 1.0 | 0.5 | 3.0 | 3.0 | 3.0 |
| Inorganic filler | Spherical SiO₂ | 400 | 400 | 260 | 260 | 260 |

| Properties | Unit | E13 | E14 | E15 | E16 | E17 |
|---|---|---|---|---|---|---|
| Solder floating | % | 0 | 0 | 0 | 0 | 0 |
| crack rate | | | | | | |
| Copper foil peeling | lb/in | 4.40 | 4.50 | 4.70 | 4.80 | 4.80 |
| strength | | | | | | |
| Z-axis percent of | % | 1.49 | 1.52 | 1.53 | 1.58 | 1.59 |
| thermal expansion | | | | | | |
| Water absorption | % | 0.35 | 0.33 | 0.20 | 0.21 | 0.23 |
| ratio | | | | | | |
| Dissipation factor | / | 0.0045 | 0.0046 | 0.0041 | 0.0043 | 0.0044 |

TABLE 4
The components (in parts by weight) and the property testing
results of the resin composition of Examples E18 to E22

| Components | | E18 | E19 | E20 | E21 | E22 |
|---|---|---|---|---|---|---|
| (A) | A1 | — | 100 | — | 5 | — |
| unhydrogenated | A2 | 100 | — | — | 10 | 80 |
| maleic anhydride- | A3 | — | — | 100 | — | 5 |
| modified first | A4 | — | — | — | 10 | — |
| polyolefin | A5 | — | — | — | 5 | 10 |
| | A6 | — | — | — | 70 | — |
| | A7 | — | — | — | — | 5 |
| (B) acrylate | SR833S | 60 | — | — | 20 | 50 |
| monomer or its | SR368NS | — | 30 | 70 | 20 | — |
| oligomer | Oligomer of | — | — | — | — | — |
| | SR833S | | | | | |
| | SR295 NS | — | — | — | — | — |
| | SR399 NS | — | — | — | — | — |
| | DPHA | — | — | — | — | — |
| (C) | P1 | 10 | — | — | 15 | 5 |
| benzocyclobutene- | P2 | — | — | — | 5 | 20 |
| modified second | P3 | — | 25 | — | 5 | 3 |
| polyolefin | P4 | — | — | 30 | 3 | 10 |
| | P5 | — | — | 10 | 5 | — |
| | P6 | — | 15 | — | — | 7 |
| | P7 | 30 | — | — | 2 | — |
| | P8 | — | — | — | 3 | — |
| | P9 | — | — | — | 2 | 1 |
| | P10 | — | — | — | — | 2 |
| Other polyolefin | Ricon 130 | — | — | — | — | 10 |
| different from (A) | Ricon100 | — | — | — | — | — |
| and (C) | FG1901 | — | — | — | — | — |
| Unsaturated | BVPE | — | — | — | 5 | 20 |
| carbon-carbon | DVB | — | — | — | 10 | — |
| double bond- | | | | | | |
| containing | | | | | | |
| crosslinking agent | | | | | | |
| Curing accelerator | DCP | 3.0 | 6.0 | 1.0 | 1.0 | 4.0 |
| Inorganic filler | Spherical SiO₂ | 260 | 200 | 300 | 260 | 260 |

| Properties | Unit | E18 | E19 | E20 | E21 | E22 |
|---|---|---|---|---|---|---|
| Solder floating | % | 0 | 0 | 0 | 0 | 0 |
| crack rate | | | | | | |
| Copper foil peeling | lb/in | 5.00 | 4.90 | 5.10 | 5.00 | 4.90 |
| strength | | | | | | |
| Z-axis percent of | % | 1.61 | 1.60 | 1.62 | 1.41 | 1.45 |
| thermal expansion | | | | | | |
| Water absorption | % | 0.25 | 0.21 | 0.32 | 0.24 | 0.28 |
| ratio | | | | | | |
| Dissipation factor | / | 0.0045 | 0.0046 | 0.0044 | 0.0042 | 0.0040 |

TABLE 5
The components (in parts by weight) and the property testing results
of the resin composition of Comparative Examples C1 to C5

| Components | | C1 | C2 | C3 | C4 | C5 |
|---|---|---|---|---|---|---|
| (A) | A1 | — | — | — | — | — |
| unhydrogenated | A2 | 100 | 100 | 100 | 100 | — |
| maleic anhydride- | A3 | — | — | — | — | — |
| modified first | A4 | — | — | — | — | — |
| polyolefin | A5 | — | — | — | — | — |
| | A6 | — | — | — | — | — |
| | A7 | — | — | — | — | — |
| (B) acrylate | SR833S | 60 | 60 | 0 | 110 | 60 |
| monomer or its | SR368NS | — | — | — | — | — |
| oligomer | Oligomer of | — | — | — | — | — |
| | SR833S | | | | | |
| | SR295 NS | — | — | — | — | — |
| | SR399 NS | — | — | — | — | — |
| | DPHA | — | — | — | — | — |
| (C) | P1 | 0 | 180 | 40 | 40 | 40 |
| benzocyclobutene- | P2 | — | — | — | — | — |
| modified second | P3 | — | — | — | — | — |
| polyolefin | P4 | — | — | — | — | — |
| | P5 | — | — | — | — | — |
| | P6 | — | — | — | — | — |
| | P7 | — | — | — | — | — |
| | P8 | — | — | — | — | — |
| | P9 | — | — | — | — | — |
| | P10 | — | — | — | — | — |
| Other polyolefin | Ricon 130 | — | — | — | — | 100 |
| different from (A) | Ricon100 | — | — | — | — | — |
| and (C) | FG1901 | — | — | — | — | — |
| Unsaturated | BVPE | — | — | — | — | — |
| carbon-carbon | DVB | — | — | — | — | — |
| double bond- | | | | | | |
| containing | | | | | | |
| crosslinking agent | | | | | | |
| Curing accelerator | DCP | 3.0 | 3.0 | 3.0 | 3.0 | 3.0 |
| Inorganic filler | Spherical SiO₂ | 260 | 260 | 260 | 260 | 260 |

| Properties | Unit | C1 | C2 | C3 | C4 | C5 |
|---|---|---|---|---|---|---|
| Solder floating | % | 45 | 5 | 8 | 25 | 21 |
| crack rate | | | | | | |
| Copper foil peeling | lb/in | 4.20 | 3.10 | 3.20 | 4.60 | 2.50 |
| strength | | | | | | |
| Z-axis percent of | % | 1.86 | 1.12 | 1.77 | 1.81 | 1.42 |
| thermal expansion | | | | | | |
| Water absorption | % | 0.46 | 0.09 | 0.12 | 0.44 | 0.19 |
| ratio | | | | | | |
| Dissipation factor | / | 0.0052 | 0.0029 | 0.0027 | 0.0052 | 0.0036 |

TABLE 6
The components (in parts by weight) and the property testing results
of the resin composition of Comparative Examples C6 to C10

| Components | | C6 | C7 | C8 | C9 |
|---|---|---|---|---|---|
| (A) | A1 | — | — | — | — |
| unhydrogenated | A2 | — | — | 100 | 100 |
| maleic anhydride- | A3 | — | — | — | — |
| modified first | A4 | — | — | — | — |
| polyolefin | A5 | — | — | — | — |
| | A6 | — | — | — | — |
| | A7 | — | — | — | — |
| (B) acrylate | SR833S | 60 | 60 | 60 | 60 |
| monomer or its | SR368NS | — | — | — | — |
| oligomer | Oligomer of | — | — | — | — |
| | SR833S | | | | |
| | SR295 NS | — | — | — | — |
| | SR399 NS | — | — | — | — |
| | DPHA | — | — | — | — |
| (C) | P1 | 40 | 40 | — | — |
| benzocyclobutene- | P2 | — | — | — | — |
| modified second | P3 | — | — | — | — |
| polyolefin | P4 | — | — | — | — |
| | P5 | — | — | — | — |
| | P6 | — | — | — | — |
| | P7 | — | — | — | — |
| | P8 | — | — | — | — |
| | P9 | — | — | — | — |
| | P10 | — | — | — | — |
| Other polyolefin | Ricon 130 | — | — | 40 | — |
| different from (A) | Ricon100 | — | 100 | — | 40 |
| and (C) | FG1901 | 100 | — | — | — |
| Unsaturated | BVPE | — | — | — | — |
| carbon-carbon | DVB | — | — | — | — |
| double bond- | | | | | |
| containing | | | | | |
| crosslinking agent | | | | | |
| Curing accelerator | DCP | 3.0 | 3.0 | 3.0 | 3.0 |
| Inorganic filler | Spherical | 260 | 260 | 260 | 260 |
| | SiO₂ | | | | |

| Properties | Unit | C6 | C7 | C8 | C9 |
|---|---|---|---|---|---|
| Solder floating | % | The | 17 | 60 | 32 |
| crack rate | | sample | | | |
| Copper foil peeling | lb/in | is unable | 2.70 | 3.10 | 3.40 |
| strength | | to be | | | |
| Z-axis percent of | % | prepared | 1.62 | 2.15 | 2.30 |
| thermal expansion | | | | | |
| Water absorption | % | | 0.19 | 0.25 | 0.26 |
| ratio | | | | | |
| Dissipation factor | / | | 0.0037 | 0.0045 | 0.0046 |

In the present disclosure, the property tests of the Examples and Comparative Examples are performed by preparing test specimens (samples) in the following manner and then performing the tests under specific test conditions.

### 1. Inorganic Filler-Containing Varnish

The components of each Example or each Comparative Example are added into a stirring tank according to Table 1 to Table 6, stirred, completely dissolved at 25° C. to 80° C., and well-mixed to form a resin composition including inorganic filler, which is called a inorganic filler-containing varnish.

### 2. Copper-Clad Resin Cured Product

A mold (such as a fully cured laminate) is prepared, grooves are created on the mold, and the inorganic filler-containing varnish prepared from the Examples or Comparative Examples is placed into the grooves, and copper foils (such as 1 ounce hyper very low profile (HVLP) copper foil) are covered on the upper and lower surfaces of the mold, followed by curing the varnish at high temperature and high pressure to C-stage, wherein a curing temperature is between 200° C. and 210° C., a curing time is 120 to 150 minutes, and a pressure is between 400 psi and 500 psi. After the varnish is completely cured, a CNC molding machine (model TQZX-II) is used to mill the sample in the shape of a groove with a milling cutter with a diameter of 1.6 mm to obtain a resin cured product with copper foils covering the upper and lower surfaces (abbreviated as copper-clad resin cured product), which is used to measure the copper foil peeling strength.

### 3. Copper-Free Resin Cured Product

The copper-clad resin cured product was etched to remove the copper foil on the upper and lower surfaces to obtain a copper-free resin cured product, which is used to measure the dissipation factor, the Z-axis percent of thermal expansion and the water absorption ratio.

The property testing methods and analysis items of the samples are as follows:

### 1. Solder Floating Crack Rate

### (1) Preparation of Hole Plugged Copper-Clad Laminate

Two 3-ounce high-temperature elongation (HTE) copper foils and two prepregs (such as product EM-890, available from Elite Electronic Material (Kunshan) Co., Ltd.) made from 106 glass fiber fabrics are prepared. They are stacked in an order of one HVLP copper foil, two prepregs, one HVLPcopper foil, followed by lamination under vacuum at 500 psi and 200° C. for 2 hours to form a copper-clad inner laminate. Both sides of the copper-clad inner laminate are subjected to a brown oxidation and drilling, followed by hole plugging, wherein the holes are filled with inorganic filler-containing varnish prepared from each Examples or Comparative Examples to obtain a hole plugged copper-clad inner laminate. The hole plugged copper-clad inner laminate is placed in an oven at 175° C. and baked for 1 hour, and then naturally cooled down to 80° C. to obtain a hole plugged copper-clad laminate.

### (2) Preparation of Evaluation Laminate

Four prepregs (such as product EM-890, available from Elite Electronic Material (Kunshan) Co., Ltd.) made from 1078 L-glass fiber fabrics, and one hole plugged copper-clad laminate which is mentioned above are prepared. They are stacked alternately in an order of two prepregs, one hole plugged copper-clad laminate, and two prepregs, and a HVLP copper foil with a thickness of 18 μm is stacked on each of the outermost surfaces, followed by lamination under vacuum at 500 psi and 200° C. for 2 hours to form an Evaluation laminate.

### (3) Measurement of Solder Floating Crack Rate

The evaluation laminate is cut into 18 specimens of 8 centimeters×10 centimeters. Each specimen is placed in a 288° C. tin bath for 10 seconds to undergo solder floating, then removed and cooled for 120 seconds, and this process is repeated 20 times. The specimen is then sliced at the drilling area and inspected under an optical microscope to check for any crack in the resin filling area in the holes. Crack refers to cracks inside the resin. For single evaluation laminate, the solder floating crack rate=(number of delaminated holes×100%)/total number of holes. A lower solder floating crack rate is preferable. The lower the solder floating crack rate is, the stronger the bonding force between the resin components is, and the higher the yield of the hole plugging process is.

### 2. Copper Foil Peeling Strength (Peeling Strength, P/S)

The copper-clad resin cured product mentioned above are cut into rectangular samples with a width of 24 mm and a length greater than 60 mm, and the samples are etched to remove the surface copper foil, and only a strip copper foil with a width of 3.18 mm and a length of greater than 60 mm is remained. The samples are measured for the force required to peel the copper foil away from the surface of the cured product at room temperature (about 25° C.) by a universal tensile tester by reference to IPC-TM-650 2.4.8(2012), in lb/in.

3. Z-Axis Percent of Thermal Expansion (Percent of Thermal Expansion, z-Axis, Z-PTE)

The copper-free resin cured product are selected as samples, and heated at a rate of 10° C. per minute from 50° C. to 260° C., and measured for Z-axis percent of thermal expansion (in %) in a temperature range of 50° C. to 260° C. by thermal mechanical analysis (TMA) by reference to IPC-TM-650 2.4.24.5. When the Z-axis percent of thermal expansion of the resin cured product is less than or equal to 1.8%, the difference of the Z-axis percent of thermal expansion greater than or equal to 0.05% represents that there is a significant difference between different samples (since the resin cured product does not include reinforcement material, there is a significant technical difficulty to lower the Z-axis percent of thermal expansion).

### 4. Water Absorption Ratio

The copper-free resin cured product above are selected as samples. By reference to IPC-TM-650 2.6.2.1(2012), the samples are placed in a 105±10° C. oven and baked for 1 hour and then cooled at room temperature (about 25° C.) for 10 minutes, and then the samples are weighed as W₁. By reference to IPC-TM-650 2.6.16.1, the samples then undergo a pressure cooking test (PCT) for 3 hours of moisture absorption (test temperature at 121° C., and relative humidity 100%). After taking out and cooling the samples and wiping out the water on the surface of the samples, the samples are weighed as W₂. The water absorption ratio is calculated by the following formula:

Water absorption ratio (%)=[(W2−W1)/W1]×100%

### 5. Dissipation Factor (Df)

The copper-free resin cured product above are selected as samples. The dissipation factors of the samples are measured at room temperature (about 25° C.) and at a frequency of 10 GHz by a microwave dielectrometer (available from AET, Inc.) by reference to JIS C2565. When the Df value measured at a frequency of 10 GHz is less than 0.005, the difference of Df value greater than or equal to 0.0001 represents that there is a significant difference between the dissipation factors of different resin cured products (there is a significant technical difficulty).

According to the property testing results in Table 1 to Table 6, the following phenomena can be clearly observed:

The benzocyclobutene-modified second polyolefin included in the resin composition of Examples E1 to E14 is any one of benzocyclobutene-modified heteroatom-containing polyolefin or benzocyclobutene-modified non-heteroatom-containing polyolefin, and the benzocyclobutene-modified second polyolefin included in the resin composition of Examples E15 to E22 is a combination of benzocyclobutene-modified heteroatom-containing polyolefin and benzocyclobutene-modified non-heteroatom-containing polyolefin. Compared to the articles made from the resin composition of Examples E1 to E14, the articles made from the resin composition of Examples E15 to E22 have significant improvement in copper foil peeling strength.

The resin composition of Example E1, Example E3, and Examples E5 to E22 include 20 to 120 parts by weight of the benzocyclobutene-modified second polyolefin, the resin composition of Example E2 includes 5 parts by weight of the benzocyclobutene-modified second polyolefin, the resin composition of Example E4 includes 160 parts by weight of the benzocyclobutene-modified second polyolefin. Compared to the articles made from the resin composition of Example E2 and Example E4, the articles made from the resin composition of Example E1, Example E3, and Examples E5 to E22 have significant improvement in copper foil peeling strength or Z-axis percent of thermal expansion.

The acrylate monomer and/or its oligomer of the resin composition of Examples E1 to E8 and Examples E12 to E22 has two acrylate groups or three acrylate groups, and the acrylate monomer and/or its oligomer of the resin composition of Examples E9 to E11 has four to six acrylate groups. Compared to the articles made from the resin composition of Examples E9 to E11, the articles made from the resin composition of Examples E1 to E8 and Examples E12 to E22 have significant improvement in Z-axis percent of thermal expansion.

According to the comparison of Examples E1 to E22 and Comparative Examples C1 to C2, it can be known that with respect to 100 parts by weight of the unhydrogenated maleic anhydride-modified first polyolefin, when the amount of the benzocyclobutene-modified second polyolefin is not in the range of 5 to 160 parts by weight, the article made by such resin composition has significant deterioration in solder floating crack rate.

According to the comparison of Examples E1 to E22 and Comparative Examples C3 to C4, it can be known that with respect to 100 parts by weight of the unhydrogenated maleic anhydride-modified first polyolefin, when the amount of the acrylate monomer, its oligomer or a combination thereof (the acrylate monomer having two or more unsaturated carbon-carbon double bonds) is not in a range of 20 to 100 parts by weight, the article made by such resin composition has significant deterioration in solder floating crack rate and Z-axis percent of thermal expansion.

According to the comparison of Examples E1 to E22 and Comparative Examples C1 and C3, it can be known that when the resin composition lacks the benzocyclobutene-modified second polyolefin (Comparative Example C1) or the acrylate monomer, its oligomer or a combination thereof (the acrylate monomer having two or more unsaturated carbon-carbon double bonds) (Comparative Example C3), the article made by such resin composition has significant deterioration in solder floating crack rate and Z-axis percent of thermal expansion.

The unhydrogenated maleic anhydride-modified first polyolefin, benzocyclobutene-modified second polyolefin and the acrylate monomer, its oligomer or a combination thereof (the acrylate monomer having two or more unsaturated carbon-carbon double bonds) are used in Examples E1 to E22. Compared to Comparative Example C5 and Comparative Example C7 using other polyolefin different from the unhydrogenated maleic anhydride-modified first polyolefin, the benzocyclobutene-modified second polyolefin and the acrylate monomer, its oligomer or a combination thereof (the acrylate monomer having two or more unsaturated carbon-carbon double bonds) (the unmodified polyolefin Ricon 130 is added in C5, and the unmodified polyolefin Ricon 100 is added in C7), the articles made from the resin composition of Example E1 to E22 have significant improvement in at least one of following properties: solder floating crack rate and copper foil peeling strength. In addition, the hydrogenated maleic anhydride-modified styrene-butadiene copolymer FG1901 is added in Comparative Example C6, and since FG1901 is insoluble, the sample is unable to be prepared.

The unhydrogenated maleic anhydride-modified first polyolefin, benzocyclobutene-modified second polyolefin and the acrylate monomer, its oligomer or a combination thereof (the acrylate monomer having two or more unsaturated carbon-carbon double bonds) are used in Example E1 to E22. Compared to Comparative Example C8 and Comparative Example C9 using the unhydrogenated maleic anhydride-modified first polyolefin, other polyolefin different from the benzocyclobutene-modified second polyolefin, and the acrylate monomer, its oligomer or a combination thereof (the acrylate monomer having two or more unsaturated carbon-carbon double bonds) (the unmodified polyolefin Ricon 130 is added in C8, and the unmodified polyolefin Ricon 100 is added in C9), the articles made from the resin composition of Example E1 to E22 have significant improvement in at least one of following properties: solder floating crack rate, copper foil peeling strength and Z-axis percent of thermal expansion.

Although the present disclosure has been disclosed in the above embodiments, it is not intended to limit the present disclosure. Any modifications and refinements made without departing from the spirit and scope of the present disclosure are within the scope of the patent protection of the present disclosure. The scope of protection of the present disclosure is defined by appended claims.

What is claimed is:

1. A resin composition, comprising:
a component (A): 100 parts by weight of an unhydrogenated maleic anhydride-modified first polyolefin;
a component (B): 20 to 100 parts by weight of an acrylate monomer, its oligomer or a combination thereof, wherein the acrylate monomer has at least two unsaturated carbon-carbon double bonds; and
a component (C): 5 to 160 parts by weight of a benzocyclobutene-modified second polyolefin.

2. The resin composition of claim 1, wherein the unhydrogenated maleic anhydride-modified first polyolefin comprises any one of a maleic anhydride-adducted polybutadiene, a maleic anhydride-adducted polyisoprene, a maleic anhydride-adducted styrene-butadiene copolymer, a maleic anhydride-adducted styrene-isoprene copolymer, a maleic anhydride-styrene copolymer or a combination thereof.

3. The resin composition of claim 1, wherein the resin composition comprises 20 to 120 parts by weight of the benzocyclobutene-modified second polyolefin.

4. The resin composition of claim 1, wherein the benzocyclobutene-modified second polyolefin comprises any one of a benzocyclobutene-modified heteroatom-containing polyolefin, a benzocyclobutene-modified non-heteroatom-containing polyolefin or a combination thereof.

5. The resin composition of claim 4, wherein the benzocyclobutene-modified second polyolefin comprises a benzocyclobutene-modified heteroatom-containing polyolefin and a benzocyclobutene-modified non-heteroatom-containing polyolefin, and a mass ratio of the benzocyclobutene-modified non-heteroatom-containing polyolefin to the benzocyclobutene-modified heteroatom-containing polyolefin is 1:3 to 7:1.

6. The resin composition of claim 4, wherein the heteroatom-containing polyolefin comprises any one of a maleic anhydride-adducted polybutadiene, a maleic anhydride-adducted polyisoprene, a maleic anhydride-adducted styrene-butadiene copolymer, a maleic anhydride-adducted styrene-isoprene copolymer, a vinyl-polybutadiene-urethane polymer, a silane-modified styrene-butadiene copolymer, an acryloyl group-terminated polybutadiene, an epoxy group-containing polybutadiene or a combination thereof.

7. The resin composition of claim 4, wherein the non-heteroatom-containing polyolefin comprises any one of a polybutadiene, a polyisoprene, a styrene-butadiene copolymer, a styrene-isoprene copolymer, a styrene-butadiene-divinylbenzene polymer, a styrene-ethylene-divinylbenzene polymer, a styrene-ethylvinylbenzene-divinylbenzene polymer or a combination thereof.

8. The resin composition of claim 1, wherein the acrylate monomer comprises any one of a tricyclodecane dimethanol di(meth)acrylate, a dioxane glycol di(meth)acrylate, a di(propylene glycol) di(meth)acrylate, a tris(2-hydroxyethyl) isocyanurate tri(meth)acrylate, a pentaerythritol tri(meth)acrylate, a pentaerythritol tetra(meth)acrylate, a di(trimethylolpropane) tetra(meth)acrylate, a dipentaerythritol penta(meth)acrylate, a dipentaerythritol hexa(meth)acrylate or a combination thereof.

9. The resin composition of claim 1, wherein the acrylate monomer has two acrylate groups or three acrylate groups.

10. The resin composition of claim 1, wherein the acrylate monomer or its oligomer has a glass transition temperature greater than or equal to 90° C. after cured.

11. The resin composition of claim 1, wherein the acrylate monomer or its oligomer has a glass transition temperature greater than or equal to 150° C. after cured.

12. The resin composition of claim 1, wherein the resin composition does not comprise an organic solvent.

13. The resin composition of claim 1, wherein the resin composition further comprises any one of a polyolefin different from the unhydrogenated maleic anhydride-modified first polyolefin and the benzocyclobutene-modified second polyolefin, an unsaturated carbon-carbon double bond-containing crosslinking agent, a benzoxazine resin, an epoxy resin, an active ester, a phenol resin, an amine curing agent, a polyamide, a polyimide, a cyanate ester resin or a combination thereof.

14. The resin composition of claim 1, wherein the resin composition further comprises any one of an inorganic filler, a flame retardant, a curing accelerator, a polymerization inhibitor, a coloring agent, a silane coupling agent, a surfactant, a toughening agent or a combination thereof.

15. An article made from the resin composition of claim 1, wherein the article comprises a prepreg, a resin film, a laminate or a printed circuit board.

16. An article made from the resin composition of claim 1, wherein the article comprises a resin cured product obtained by curing the resin composition.

17. The article of claim 16, wherein the article has at least one of following properties:
a solder floating crack rate as measured by reference to IPC-TM-650 2.4.13.1 of 0%;
a copper foil peeling strength as measured by reference to IPC-TM-650 2.4.8 of greater than or equal to 3.5 lb/in;
a Z-axis percent of thermal expansion as measured by reference to IPC-TM-650 2.4.24.5 of less than or equal to 1.72%;
a water absorption ratio as measured by reference to IPC-TM-650 2.6.2.1 and IPC-TM-650 2.6.16.1 of less than or equal to 0.39%; and
a dissipation factor as measured at 10 GHz by reference to JIS C2565 of less than or equal to 0.0048.

18. A use of the resin composition of claim 1 in a resin filling process for printed circuit boards.

19. The use of claim 18, wherein the resin filling process for printed circuit boards comprises a hole plugging process for printed circuit boards, a groove filling process for printed circuit boards, or a circuit filling process for printed circuit boards.

20. The use of claim 19, wherein in the hole plugging process for printed circuit boards, at least one hole of the printed circuit boards is filled with a resin cured product of the resin composition, in the groove filling process for printed circuit boards, at least one groove of the printed circuit boards is filled with the resin cured product of the resin composition, and in the circuit filling process for printed circuit boards, at least one circuit open area of the printed circuit boards is covered with the resin cured product of the resin composition.
